(19) United States
(12) Patent Application Publication
(10) Pub. No.: US 2013/0344703 A1
(43) Pub. Date: Dec. 26, 2013

(54) FILM FORMING METHOD AND FILM FORMING APPARATUS

(71) Applicant: TOKYO ELECTRON LIMITED, Minato-ku (JP)

(72) Inventors: Masahiro SHIMIZU, Yamanashi (JP); Hitoshi Itoh, Yamanashi (JP)

(73) Assignee: TOKYO ELECTRON LIMITED, Minato-ku (JP)

(21) Appl. No.: 13/974,876

(22) Filed: Aug. 23, 2013

Related U.S. Application Data
(63) Continuation of application No. PCT/JP2012/054314, filed on Feb. 22, 2012.

(30) Foreign Application Priority Data
Feb. 25, 2011 (JP) 2011-040117
Sep. 27, 2011 (JP) 2011-211512
Sep. 27, 2011 (JP) 2011-211513

(51) Int. Cl. B05D 7/02; H01B 19/04; H01L 21/02; H05K 3/10

(52) U.S. Cl. CPC B05D 7/02; H05K 3/10; H01B 19/04; H01L 21/02
USPC 438/758; 427/541; 427/532

(57) ABSTRACT

In a film forming method, a coating composition containing film components is coated on a plastic substrate to form a coating film. By irradiating electromagnetic waves to the coating film, the coating film is dried and/or modified to form a film. The film can be a conductor film, a semi-conductor film or a dielectric film. When forming a conductor film, a coating composition containing metallic nanoparticles is used as the coating composition; when forming a semi-conductor film, an organic semi-conductor material is used as the coating composition; and when forming a dielectric film, an organic dielectric material is used as the coating composition.

### CROSS REFERENCE TO RELATED APPLICATIONS

This application is a Continuation Application of and claims the benefit of priority from PCT International Application No. PCT/JP2012/054314 filed on Feb. 22, 2012, which designated the United States, the entire contents of which are incorporated herein by reference. This application also claims the benefit of priority from Japanese Application No. 2011-040117 filed on Feb. 25, 2011, Japanese Application No. 2011-211512 filed on Sep. 27, 2011, and Japanese Application No. 2011-211513 filed on Sep. 27, 2011, the entire contents of each of which are incorporated herein by reference.

### FIELD OF THE INVENTION

The present invention relates to a film forming method and a film forming apparatus which form a film on a plastic substrate by coating.

### BACKGROUND OF THE INVENTION

Recently, a film forming method is being studied to form devices on a low-cost and flexible plastic substrate for a large-size device such as a solar cell, a large-size display or the like. The plastic substrate is advantageous in that it can be installed on a curved surface and it is not easily damaged compared to a large-size device formed on a conventional glass substrate. Thus, the plastic substrate is expected to be applicable to various areas. A large-size display requires a TFT (Thin Film Transistor), and the TFT uses a conductor film such as a wiring, an electrode or the like, a semiconductor film constituting a transistor, and a dielectric film such as a gate film or the like.

In the case of forming a device pattern on the plastic substrate, by a conventional photolithography technique requires, an extremely high cost. Therefore, a film formation using coating printing which can form a device pattern at a low cost per area has been attempted.

For example, as for a technique for forming a conductor film by using coating printing, a technique using a coating composition obtained by adding a binder, a solvent or the like to metallic particles is disclosed in Patent Document 1.

As for other techniques for forming a semiconductor film by using coating printing, there are known techniques using tetrabenzoporphyrin (BP) (Patent Document 2), poly-3-hexylthiophene (P3HT) (Patent Document 3), and alkylbenzotheophene (Cu-BTBT) (Patent Document 4).

Further, as for a technique for forming a dielectric film by using coating printing, a technique using an organic dielectric (gate insulating) material such as polyvinylphenol (PVP) or cyanoethyl pullulan (CyEPL) for a dielectric film (gate insulating film) of TFT is disclosed in Patent Document 5.

Since, however, other additives such as a solvent, a polymer or the like is contained in the coating composition used for the coating printing, it is difficult to obtain desired properties only by coating due to the presence of the solvent, the polymer, or the like contained therein. Therefore, it is necessary to remove them by resistance heating. This is disclosed in Patent Document 1.

Patent Document 1: Japanese Patent Application Publication No. 2001-243836

Patent Document 2: Japanese Patent Application Publication No. 2008-016834

Patent Document 3: WO 2009/008323 Pamphlet

Patent Document 4: Japanese Patent Application Publication No. 2009-283786

Patent Document 5: Japanese Patent Application Publication No. 2006-24790

However, in a method of removing a solvent or the like by using resistance heating, when the plastic substrate is heated to a temperature at which the solvent or the like can be completely removed, the temperature of the plastic substrate exceeds heat resistant temperature thereof. Thus, the plastic substrate needs to be heated at a temperature, lower than the heat resistant temperature. In this case, however, there may occur problems such as increase in drying time or deterioration of film quality due to insufficient removal of the solvent or other additives. For example, when the conductor film thus formed is used as wiring, the electrical conductivity is decreased. When the dielectric film is used for a gate insulating film, problems such as decrease in capacity, increase in leakage current, deterioration of stability of a film, or deterioration of reliability of a film occur. Accordingly, currently, it is difficult to apply a plastic substrate, and the advantages thereof such as low cost, flexibility, and capability of dealing with scaling up cannot be fully utilized.

### SUMMARY OF THE INVENTION

In view of the above, the present invention provides a film forming method and a film forming apparatus capable of forming a film having good characteristics on a plastic substrate by using a coating printing technique.

In accordance with a first aspect of the present invention, there is provided a film forming method including: coating, on a plastic substrate, a coating composition containing film components to form a coating film; and irradiating the coating film with electromagnetic waves to dry and/or modify the coating film, and form a film.

In the first aspect, the film may be a conductor film. In this case the coating composition contains metallic nanoparticles, and the coating film is formed as a wiring formed of the metallic nanoparticles by irradiating the coating film with the electromagnetic waves.

Further, the coating film may be formed as a wiring pattern before the annealing, and the electromagnetic waves may be irradiated to at least the wiring pattern. In addition, the coating film may be coated on an entire surface of the plastic substrate, and a wiring pattern may be formed after the electromagnetic waves are irradiated to the coating film coated on the entire surface.

Further, the coating film may be processed by a gas plasma before annealing is performed by irradiating the electromagnetic waves. In addition, the electromagnetic waves may be irradiated while spraying the coating composition onto the plastic substrate and then, a wiring pattern may be formed on the coating film formed on the plastic substrate.

The coating composition may contain metallic nanoparticles, a solvent, and a dispersing agent. The metallic nanoparticles may contain any of Ag, Cu and Al, or an alloy containing any of Ag, Cu and Al.

In the first aspect, the film may be a semiconductor film. In this case, the coating composition contains an organic semiconductor material. A frequency of the electromagnetic waves is preferably set to a frequency at which absorption of the electromagnetic waves into the plastic substrate is low and absorption of the electromagnetic waves into the coating composition containing the organic semiconductor material is high. In this case, the frequency of the electromagnetic waves may be an absorption peak value of dielectric dispersion properties of the coating composition or a value near the peak value. The coating composition may be a solution in which poly-3-hexylthiophene (P3HT), as an organic semiconductor material, is dissolved in chloroform (CHCl3). The electromagnetic waves may have a frequency of about 1 Hz to 10 kHz.

In the first aspect, the film may be a dielectric film. In this case, the coating composition contains an organic dielectric material. The frequency of the electromagnetic waves is preferably set to a frequency at which absorption of the electromagnetic waves into the plastic substrate is low and absorption of the electromagnetic waves into the coating composition containing the organic semiconductor material is high. In this case, the frequency of the electromagnetic waves may be an absorption peak value of dielectric dispersion properties of the coating composition or a value near the peak value. The coating composition may be liquid polyvinyl phenol as an organic dielectric material. The electromagnetic waves may have a frequency of about 100 Hz to 50 kHz.

In the first aspect, the electromagnetic waves may be irradiated while cooling the plastic substrate. Further, the electromagnetic waves may be irradiated in a pulsed manner. Furthermore, the electromagnetic waves may be irradiated while heating the substrate to a temperature equal to or lower than a heat resistance temperature of the plastic substrate.

In accordance with a second aspect of the present invention, there is provided a film forming apparatus, including: a processing chamber in which a predetermined atmosphere is formed; a disposing unit configured to dispose a member having a coating film formed by coating a coating composition, containing film components, on a plastic substrate in the processing chamber; and an electromagnetic wave irradiation unit configured to irradiate at least the coating film of the member with electromagnetic waves, wherein the coating film is dried and/or modified to form a film by the irradiated electromagnetic waves from the electromagnetic wave irradiation unit to the coating film.

In the second aspect, the film forming apparatus may further include a temperature control unit configured to control a temperature of the plastic substrate of the member provided in the processing chamber. Further, the disposing unit may be a supporting member for supporting the member having the coating film. The film forming apparatus may further include a cooling unit configured to cool the plastic substrate via the supporting member. The film forming apparatus may further include electromagnetic wave irradiation unit may irradiate the electromagnetic waves in a pulsed manner. Furthermore, a heating unit configured to heat the member supported by the supporting member. The electromagnetic wave irradiation unit may set a frequency of the electromagnetic waves to a frequency at which absorption of the electromagnetic waves into the coating composition is high.

### BRIEF DESCRIPTION OF THE DRAWINGS

FIG. 1 is a flowchart showing a film forming method in accordance with an embodiment of the present invention.

FIGS. 2A and 2B are optical spectroscope images of wiring formed by irradiating electromagnetic waves to a coating film containing metallic nanoparticles.

FIG. 3 shows a result of a measurement of dielectric dispersion of CHCl₃ liquid of P3HT.

FIG. 4 shows a result of a measurement of dielectric dispersion of CHCl₃.

FIG. 5 shows a result of a measurement of dielectric dispersion of PVP liquid.

FIG. 6 is a cross sectional view showing an example of a film forming apparatus for performing a film forming method in accordance with an embodiment of the present invention.

FIG. 7 is a cross sectional view showing another example of a film forming apparatus for performing a film forming method in accordance with an embodiment of the present invention.

FIG. 8 is a cross sectional view showing still another example of a film forming apparatus for performing a film forming method in accordance with an embodiment of the present invention.

### DETAILED DESCRIPTION OF THE EMBODIMENTS

Hereinafter, embodiments of the present invention will be described with reference to the accompanying drawings.

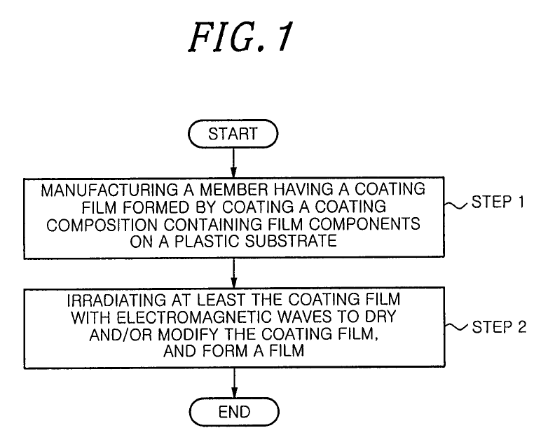

FIG. 1 is a flowchart showing a wiring forming method in accordance with an embodiment of the present invention.

First, a member having a coating film obtained by coating a coating composition, containing film components, on a plastic substrate, e.g., a device sheet for forming a device, is manufactured (step 1).

Although the plastic substrate is not particularly limited, it is preferable to use low-cost PET (polyethylene terephthalate), PEN (polyethylene naphthalate), PC (polycarbonate), PI (polyimide) or the like.

When a film is a conductor film such as wiring, an electrode or the like, a coating composition including a film component containing, e.g., metallic nanoparticles is used. When a film is a semiconductor film, a coating composition including a film component containing, e.g., an organic semiconductor material is used. When a film is a dielectric film, a coating composition including a film component containing an organic dielectric material is used. The viscosity of the coating component is controlled by appropriately mixing solvents, polymers, dispersing agents, binders, and various additives with the film component in accordance with the materials of the film components and the coating methods, so that the coating component can be coated. Typically, coating ink is used.

Metallic nanoparticles are fine metal particles having a particle size of one to several hundreds of nm. As for a metal constituting the metallic nanoparticles, a metal that can be applied to a fine metal wiring is used. A typical example of such metal is any one of Ag, Cu and Al, or an alloy containing any one of them. In this case, a coating composition can be obtained by appropriately dispersing metallic nanoparticles in a solvent.

The organic semiconductor material may be polycyclic aromatic hydrocarbon such as pentacene, anthracene, rubrene or the like; low-molecular-weight compound such as tetracyanoquinodimethane (TCNQ) or the like; or polymer such as polyacetylene, poly-3-hexylthiophene (P3HT), poly-paraphenylene vinylene (PPV), alkylbenzo thieno benzothiophene (Cu-BTBT) or the like. The coating composition using an organic semiconductor material may be, e.g., P3HT solution using chloroform (CHCl₃) as a solvent.

The organic dielectric material may be polyvinylphenol (PVP), cyanoethylpullulan (CyEPL), or the like. The coating composition using the organic dielectric material may be, e.g., liquid PVP.

As for the coating method for applying the coating composition, it is preferable to employ a method that ensures good conformability to a fine pattern. For example, ink jet printing, screen printing, microcontact print (MCP), or the like may be preferably used. In addition, a spin coating method, a bar coating method, and a reverse printing may also be used.

Next, the coating film is dried and/or modified by irradiating electromagnetic waves to at least a portion of the coating film of the member thus prepared (device sheet), and a film is formed (step 2).

In a state where the coating composition is coated, the components such as solvents, dispersing agents or the like are contained in the coating film, and in case of using metallic nanoparticles, the metallic nanoparticles are not sufficiently aggregated to approach a bulk metal structure. Therefore, the electrical conductivity is poor. Further, in the case of using an organic semiconductor material or an organic dielectric material, the component such as solvents, dispersing agents or the like are contained in the coating film, and the organic semiconductor material or the organic dielectric material does not have a desired structure. As a result, initial characteristics are hardly obtained. Therefore, either drying or modifying the coating film, or both of drying and modifying the coating film are carried out by irradiating electromagnetic waves such as microwaves or the like to the coating film formed by coating the coating composition to form a film having semiconductor characteristics or dielectric characteristics. The electromagnetic waves are preferably irradiated to at least the coating film constituting the wiring pattern. Typically, the electromagnetic waves are irradiated to the entire surface of the device sheet.

Generally, resistance heating is used for supplying energy for drying and modifying the coating film of this type. However, in the case of resistance heating, a relatively high temperature is required to obtain a film having desired characteristics (e.g. a conductor film having high electrical conductivity suitable for wiring or the like) by evaporating a solvent or the like. Moreover, when the high-temperature heating is performed by resistance heating, the structure that realizes semiconductor characteristics of the organic semiconductor material may not be formed, or the structure of the organic dielectric material may not be formed. Therefore, in the case of using the plastic substrate as in the present embodiment, the heating temperature exceeds the heat resistance temperature of the plastic substrate.

Accordingly, in the present embodiment, as for the energy for drying and/or modifying the coating film, electromagnetic wave irradiation (electromagnetic wave heating), typically, microwave heating, is used. The plastic substrate is hardly heated because electromagnetic waves transmit therethrough. The coating composition absorbs the electromagnetic waves and is directly heated by thermal radiation. Thus, physical chemical action of the coating film in a liquid state, for example, is facilitated, and the decomposition of the solvent or the modification of the coating composition progresses. As a result, a desired film is obtained. Since the drying and/or the modification can be carried out by heating only the coating film while maintaining the plastic substrate at a low temperature, the plastic substrate is applicable without problems. However, the temperature of the plastic substrate may be supplementarily increased under the heat-resistance temperature of the material of the plastic substrate.

As shown in the following Eq. (1), the electromagnetic wave heating (microwave heating) is represented by the sum of conduction loss (induction loss), dielectric loss and magnetic loss.

P=1/2×πfσ|E|²+πfε₀ε″ᵣ|E|²+πfμ₀μ″r|H|² Eq. (1)

Where, P indicates energy loss per unit volume [W/m³]; E indicates electric field [V/m]; H indicates magnetic field [A/m]; σ indicates electrical conductivity [S/m]; f indicates a frequency [s⁻¹]; ε₀ indicates permittivity of vacuum [F/m]; ε″ᵣ indicates an imaginary part of a complex permittivity; μ₀ indicates permeability of vacuum [H/m]; and μ″ᵣ indicates an imaginary part of a complex permeability.

In the electromagnetic wave heating (microwave heating), heating can be selectively performed by utilizing the difference in induction loss, dielectric loss, and magnetic loss depending on the types of materials. Meanwhile, a plastic substrate is hardly heated because it is made of a solid polymer material having small induction loss and small dielectric loss.

When the conductor film such as wiring or the like is formed, if electromagnetic waves are irradiated, the metallic nanoparticles used for forming the wiring are heated by induction loss mainly caused by an eddy current. This is because the metallic nanoparticles are conductive materials. Further, a solvent or a dispersing agent which has polarizability is heated by dielectric loss.

When electromagnetic waves are irradiated to a coating film containing a coating composition constituting the wiring pattern, a solvent or a dispersing agent is heated mainly by dielectric loss and removed by evaporation, and metallic nanoparticles are heated and aggregated mainly by induction loss. Therefore, the wiring (including an electrode) obtained by electromagnetic wave annealing can have extremely high electrical conductivity even before annealing.

The electromagnetic waves have a frequency at which absorption of the electromagnetic waves into the metallic nanoparticles is high depending on the kind of the metallic nanoparticles. Further, the electromagnetic waves have a frequency at which absorption of the electromagnetic waves into the solvent or the dispersing agent is high depending on the kind of the solvent or the dispersing agent present. Therefore, in order to effectively perform electromagnetic wave heating, it is preferable to selectively irradiate the electromagnetic waves having a frequency at which the electromagnetic waves can be effectively absorbed into the target material.

The electromagnetic waves to be irradiated preferably have a frequency of about 300 MHz to 300 GHz. Although the electromagnetic waves may be irradiated under the atmospheric atmosphere, it is preferable to irradiate the electromagnetic waves under a depressurized atmosphere. By irradiating the electromagnetic waves under the depressurized atmosphere, the carbon content of the coating composition can be more effectively removed, and the amount of metal components in the wiring can be increased. Moreover, by irradiating the electromagnetic waves under the depressurized atmosphere, the aggregation of the metallic nanoparticles can be further facilitated, and the electrical conductivity can be further increased.

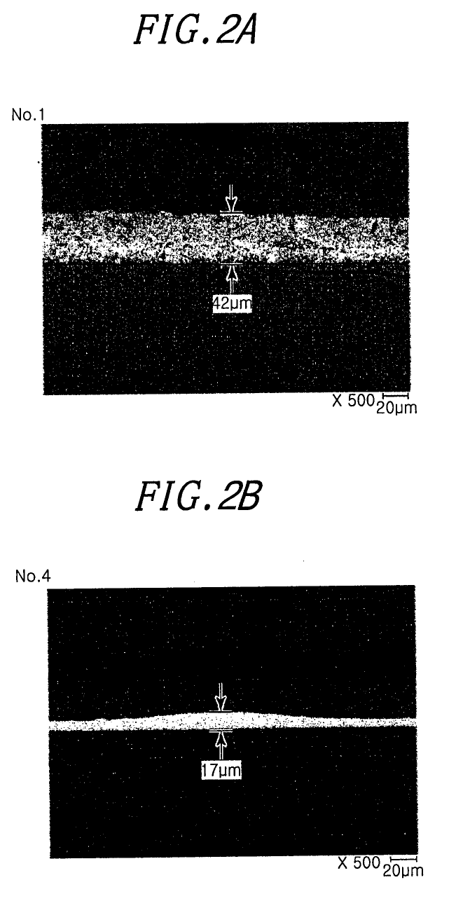

A wiring (metal film) was actually formed by using samples obtained by coating a coating composition, containing Ag nanoparticles, on the entire surface of the substrate while changing the frequency of electromagnetic waves to two levels of 107 GHz and 140 GHz. First, the annealing was performed by heating the substrate to a temperature of 100° C. and irradiating electromagnetic waves for 10 minutes under the atmospheric state. As a result, the coating composition was heated and the substrate temperature was increased to 240° C. and 270° C. in the respective samples. The optical microscope images of the wiring at that time are shown in FIGS. 2A and 2B. Further, for each sample, the sheet resistance and the composition ratio of Ag and C by EPMA (Electro Probe Micro Analyzer) are shown in Table 1. As can be seen from FIGS. 2A and 2B, although the wiring was formed under any conditions, a denser wiring was obtained when the frequency was about 107 GHz and the substrate temperature was in the range from about 100° C. to 270° C. Further, as can be seen from Table 1, by setting the frequency to 107 GHz and the substrate temperature to be in the range from about 100° C. to 270° C., the carbon residual amount in the wiring was smaller and the relatively lower sheet resistance value of about 0.019 Ω/□ was obtained, compared to the case of setting the frequency to about 140 GHz and the substrate temperature to be in the range from about 100° C. to 240° C. This result shows that the wiring obtained after the electromagnetic wave annealing can be practically used by optimizing the electromagnetic wave irradiation conditions.

TABLE 1

| | | | Sheet | Ag/C |
|---|---|---|---|---|
| | | Film | resistance | composition |
| | | thickness | value | ratio |
| No. | Annealing conditions | (μm) | (Ω/□) | (atm %) |
| 1 | 140 GHz, 100~240° C., | 42 | 0.106 | 65/35 |
| | 10 min | | | |
| 2 | 140 GHz, 100~240° C., | 42 | 0.099 | 65/35 |
| | 10 min | | | |
| 3 | 107 GHz, 100~270° C., | 8 | 0.019 | 76/24 |
| | 10 min | | | |
| 4 | 107 GHz, 100~270° C., | 17 | 0.028 | 76/24 |
| | 10 min | | | |

Hereinafter, the case of forming a semiconductor film will be described.

In order to understand the absorption properties corresponding to the frequencies of the electromagnetic waves, it is effective to measure dielectric dispersion of the coating film. The dielectric dispersion represents frequency dependence of the dielectric function. There are various polarizations of substances, such as electronic polarization, ionic polarization, orientation polarization, or the like. However, the absorption of the electromagnetic waves is increased at the frequency at which the polarization occurs. The imaginary part of the complex permittivity shows such absorption properties. Therefore, by irradiating the coating film with the electromagnetic waves having a frequency band (e.g., about 1 Hz to 10 kHz) corresponding to the peak of the imaginary part of the complex permittivity in the coating composition containing an organic semiconductor material, the energy can be effectively absorbed into the coating film without being absorbed into the plastic substrate.

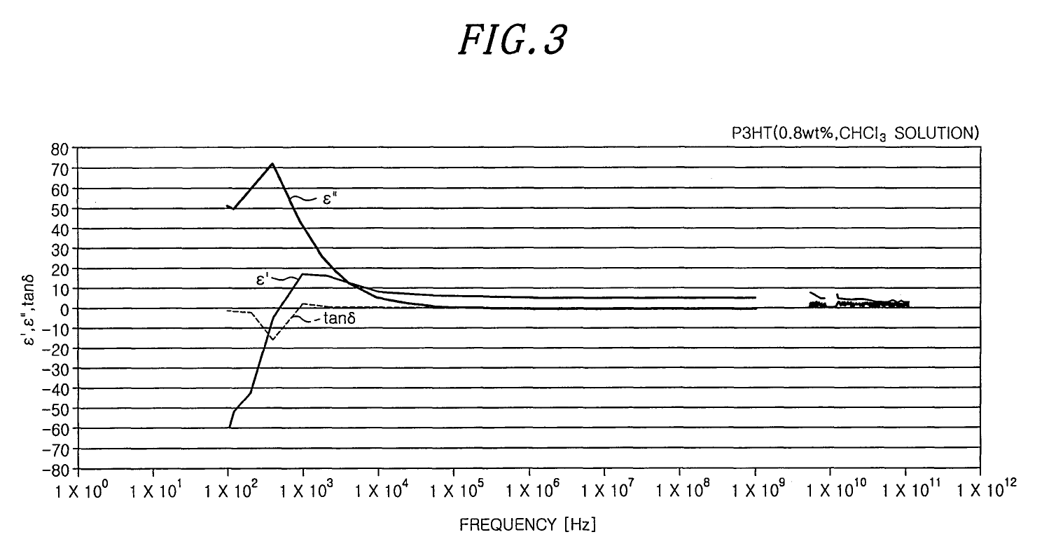

FIG. 3 is a graph showing the dielectric dispersion of the coating composition that is a solution (0.8wt % solution) in which P3HT as an organic semiconductor material is dissolved in CHCl₃ as a solvent. As shown in FIG. 3, the peak of the imaginary part (ε″) of the complex permittivity of the solution is in the low frequency region near 400 Hz, which is considered to be based on polarization by ions. Accordingly, by irradiating the electromagnetic waves with the frequency of the peak or near-peak (within the range of full width at half maximum (FWHM) of the peak), the energy can be absorbed only into the CHCl₃ solution of P3HT without being absorbed into the plastic substrate. As a consequence, drying and/or modifying the coating film can be effectively performed. In addition, in FIG. 3, the real part (ε′) of the complex permittivity and dielectric loss tangent (tan δ) are also described.

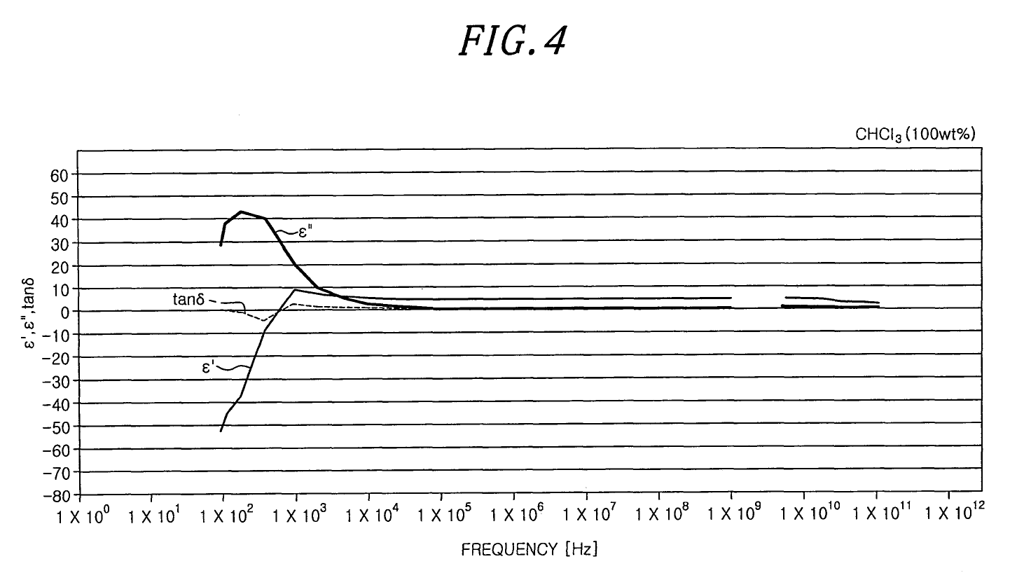

FIG. 4 shows dielectric dispersion of CHCl₃. The peak of the imaginary part exists near 200 Hz, and the absorption peak appears in the low frequency region near the absorption peak of the solution only by CHCl₃.

Hereinafter, the case of forming a dielectric film will be described.

As described above, when the dielectric dispersion of the coating film is measured, the imaginary part of the complex permittivity indicates absorption properties, the energy can be effectively absorbed into the coating film without being absorbed into the plastic substrate by irradiating the coating film with the electromagnetic waves of the frequency band (e.g., about 100 Hz to 50 kHz) corresponding to the peak of the imaginary part of the complex permittivity in the coating composition containing the organic dielectric material.

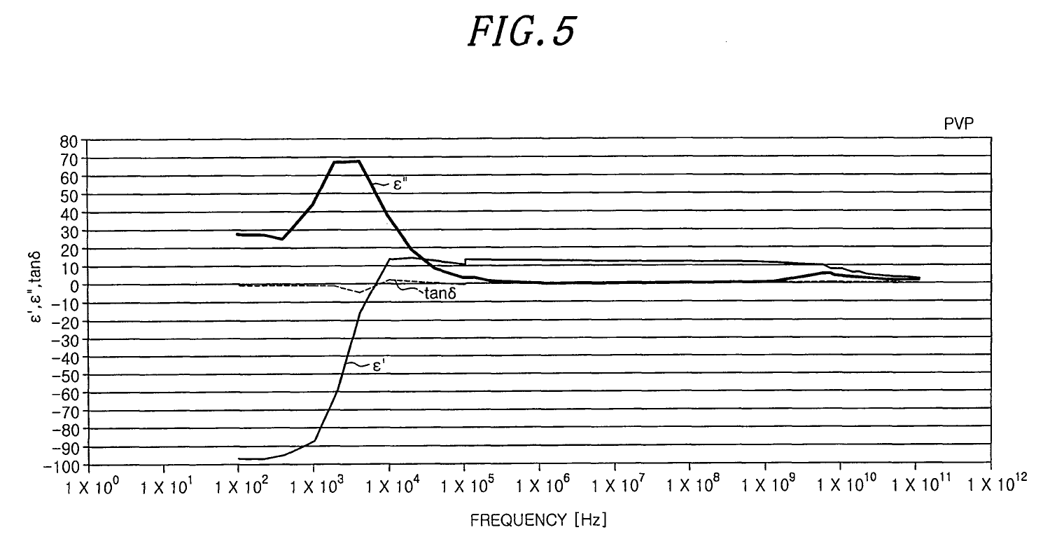

FIG. 5 is a graph showing the dielectric dispersion of the coating composition formed of liquid PVP (100wt %) as an organic dielectric material. The main component of the PVP is cyclohexanone (C₆H₁₀O). As can be seen from FIG. 5, the peak of the imaginary part (ε″) of the complex permittivity of the liquid is in the low frequency region of about 2 kHz to 4 kHz, which is considered to be based on polarization by ions. Accordingly, by irradiating the electromagnetic waves having the frequency of the peak or near-peak (within the range of full width at half maximum (FWHM) of the peak), the energy can be absorbed into the PVP liquid as the coating composition without being absorbed into the plastic substrate. As a consequence, the drying and/or the modification of the coating film can be effectively performed. Further, in FIG. 5, the real part (ε′) of the complex permittivity and dielectric loss tangent (tan δ) are also illustrated.

By irradiating the electromagnetic waves, it is possible to selectively heat only the coating film transiently. However, as the irradiation time is increased, thermal equilibrium is approached, and the temperature of the plastic substrate is increased by heat transfer. Hence, the selective heating may not be sufficiently performed. In order to avoid such problem, it is preferable to cool the plastic substrate at the opposite side to the surface thereof which the electromagnetic wave is irradiated or suppress the heating of the plastic substrate by irradiating electromagnetic waves in a pulsed manner and controlling the duty ratio of the pulse.

Hereinafter, an example of a film forming apparatus using the film forming method of the present embodiment will be described.

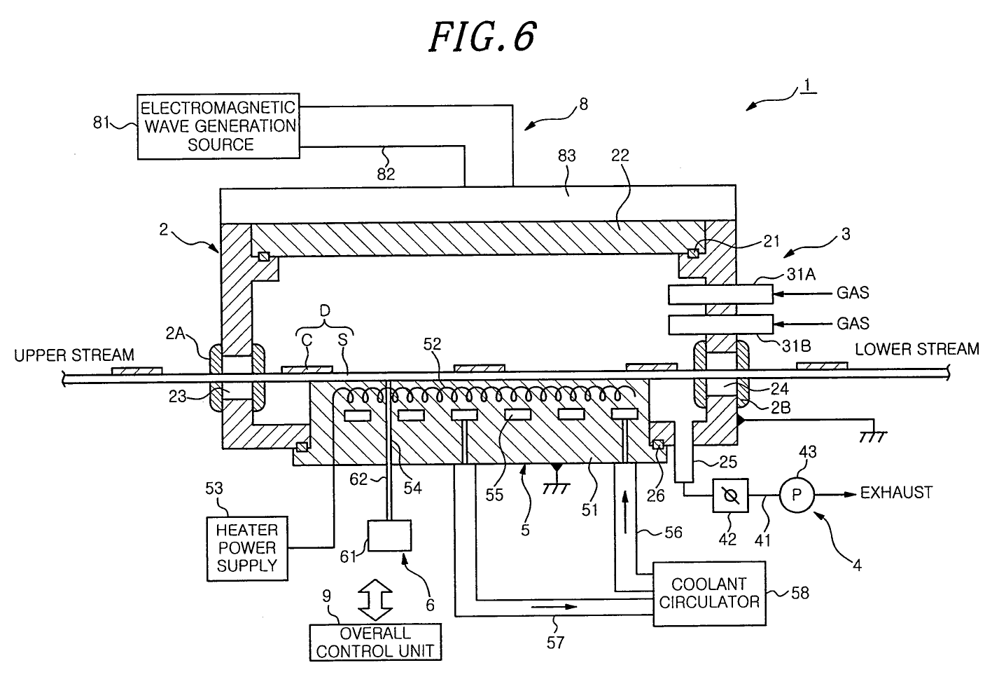

FIG. 6 is a cross sectional view showing an example of a film forming apparatus for performing the film forming method of the present embodiment. The film forming apparatus 1 includes a processing chamber 2, a gas introduction mechanism 3, a gas exhaust unit 4, a mounting table 5, a radiation thermometer 6, an electromagnetic wave supply unit 8, and an overall control unit 9.

The processing chamber 2 is made of, e.g., aluminum, and is grounded. The ceiling portion of the processing chamber 2 is opened, and a ceiling plate 22 is airtightly provided at the opening via a sealing member 21. The ceiling plate 22 is made of a dielectric material, e.g., quartz, aluminum nitride, or the like.

A loading port 23 for loading a device sheet (member) D before the irradiation of electromagnetic waves, the device sheet having a coating film (e.g., wiring pattern) formed on a plastic substrate S, and an unloading port 24 for unloading the device sheet D after the irradiation of electromagnetic waves are opened at opposite sidewalls of the processing chamber 2. The device sheet D, may be obtained by forming a coating film on the entire surface of the plastic substrate S. Further, a desired film, e.g., a conductor film, a semiconductor film and a dielectric film is formed after the electromagnetic wave (microwave) irradiation.

The loading port 23 and the unloading port 24 are provided with shutters 2A and 2B, respectively. The shutters 2A and 2B have functions of closing the loading port 23 and the unloading port 24 to prevent leakage of the electromagnetic waves and the gas in the processing chamber to the outside when a transfer unit (not shown) stops transferring the device sheet D and the electromagnetic waves (microwaves) are irradiated as described later. Further, the shutters 2A and 2B are made of soft metal, e.g., indium, copper or the like and configured to press against the device sheet D when the device sheet D is stopped. The device sheet D is wound around a supply roll (not shown). The device sheet D supplied from the supply roll is loaded into the processing chamber 2 and wound around a winding roll (not shown) provided at the opposite side.

A gas exhaust port 25 connected to the gas exhaust unit 4 is provided at a peripheral edge portion of a bottom wall of the processing chamber 2.

The gas introduction mechanism 3 has, e.g., two gas nozzles 31A and 31B penetrating through the sidewall of the processing chamber 2 and supplies a processing gas from a gas supply source (not shown) into the processing chamber 2. Here, the gas is an inert gas such as nitrogen or rare gas, e.g., argon, helium or the like. Further, the number of the gas nozzles is not limited to two and may be increased or decreased appropriately.

The gas exhaust unit 4 includes a gas exhaust passage 41 through which an exhaust gas flows, a pressure control valve 42 for controlling an exhaust pressure, and a gas exhaust pump 43 for discharging an atmosphere in the processing chamber 2. The gas exhaust pump 43 is configured to exhaust the atmosphere in the processing chamber to a predetermined vacuum level through the gas exhaust passage and the pressure control valve 42. Moreover, the atmosphere in the processing chamber 2 may be set to an atmospheric pressure without being exhausted.

The mounting table 5 is airtightly attached at the opening defined in the bottom wall of the processing chamber through a sealing member 26. The mounting table 5 is grounded. The mounting table 5 has a mounting table main body 51, and the device sheet D is mounted on the mounting table main body 51. A resistance heater 52 is installed in the mounting table main body 51 to heat the plastic substrate S by power supplied from a heater power supply 53 to the resistance heater 52. A coolant path 55 is formed in the mounting main body 51. The coolant path 55 is connected to a coolant circulator 58 for circulating a coolant via a coolant introduction line 56 and a coolant discharge line 57. When the coolant circulator 58 is operated, the coolant circulates in the coolant path 55, thereby cooling the plastic substrate S.

The radiation thermometer 6 includes a radiation thermometer main body 61 and an optical fiber 62 and can measure the temperature of the plastic substrate S. The optical fiber 62 is inserted in the through hole 54 vertically formed in the mounting table main body 51 to pass therethrough and extends downward from the upper surface of the mounting table main body 51 while penetrating through the bottom surface of the mounting table main body 51 to be connected to the radiation thermometer main body 61 provided outside the processing chamber 2. The optical fiber 62 guides the radiant light from the plastic substrate S to the radiation thermometer 61 to measure the temperature of the plastic substrate S. The temperature of the plastic substrate S can be controlled by the resistance heater 52 and the coolant flowing in the coolant path 55 based on the measured temperature under the control of the overall control unit 9.

The electromagnetic wave supply unit 8 is provided above the ceiling plate 22 of the processing chamber 2. The electromagnetic wave supply unit 8 includes a waveguide 82 and an incident antenna 83. An electromagnetic wave generation source 81 is connected to one end of the waveguide 82, and the other end of the waveguide 82 is connected to the incident antenna 83.

As for the electromagnetic wave generation source 81, it is possible to use an ultrasonic generation source, an RF power supply, a magnetron, a klystron, a gyrotron, or the like. Among them, the magnetron and the gyrotron are preferably used. The gyrotron generates electromagnetic waves (microwaves) from millimeter waves (1 mm≦wavelength≦10 mm) to sub-millimeter waves (0.1 mm≦wavelength≦1 mm). The magnetron generates electromagnetic centimeter waves (microwaves) (1 cm≦wavelength≦10 cm). The electromagnetic wave generation source 81 outputs the generated electromagnetic waves to the waveguide 82. The waveguide 82 is a metallic line for transmitting the electromagnetic waves generated by the electromagnetic wave generation source 81 to the incident antenna 83 and has a circular or a rectangular cross section. When the electromagnetic waves to be irradiated have a wide frequency range, it is preferable to install a plurality of electromagnetic wave generation sources 81 having different frequency ranges and switch them in accordance with the frequencies.

The incident antenna 83 having a plate shape is provided on a top surface of the ceiling plate 22 and made of, e.g., aluminum or copper plate having a surface coated with silver. The incident antenna 83 is provided with a plurality of specular reflection lenses or reflection mirrors (not shown) so that the electromagnetic waves transmitted from the waveguide 82 can be introduced toward the processing space in the processing chamber 2. Moreover, the incident antenna 83 may be provided at the sidewall of the processing chamber 2.

The overall control unit 9 includes a microprocessor (computer), and controls the respective components of the wiring forming apparatus 1 based on signals received from sensors, e.g., the radiation thermometer 6 and the like. The overall control unit 9 includes a storage unit for storing process recipes such as control parameters and process sequences of the wiring forming apparatus 1, an input unit, a display and the like, and controls the apparatus 1 in accordance with the selected process recipe.

Hereinafter, the operation of the film forming apparatus 1 configured as described above will be explained.

First, a device sheet D having a coating film C formed by coating a coating composition on a plastic substrate S such as PET, PEN, PC, PI or the like is prepared, and a frequency of electromagnetic waves (microwaves) generated from the electromagnetic wave generation source 81 is set to a frequency suitable for the coating composition. For example, when the coating composition contains Ag nanoparticles, the frequency of about 100 GHz is used. In the case of using CHCl₃ solution of P3HT as the coating composition, in the dielectric dispersion of FIG. 3, electromagnetic waves of a frequency band (e.g., about 1 Hz to 10 kHz) corresponding to the peak of the imaginary part of the complex permittivity, preferably electromagnetic waves with a frequency of about 400 Hz corresponding to the peak position or near-peak, are irradiated. In the case of using the liquid PVP as the coating composition, in the dielectric dispersion of FIG. 5, electromagnetic waves of a frequency band (e.g., about 100 Hz to 50 kHz) corresponding to the peak of the imaginary part of the complex permittivity, preferably electromagnetic waves with a frequency of about 2 kHz to 4 kHz corresponding to the peak position or near-peak, are irradiated.

Then, the sheet device D supplied from the supply roll (not shown) is loaded from the loading port 23 and mounted on the mounting table 5. When the atmosphere is depressurized, the loading port 23 and the unloading port 24 are closed by the shutters 2A and 2B.

A leading member having no coating film is connected to an end portion of the device sheet D and the leading member attached to the winding roll (not shown). Accordingly, the electromagnetic waves can be irradiated to the initial portion of the device sheet D.

At this time, the temperature of the plastic substrate S is controlled to a predetermined temperature by the resistance heater 52 in the mounting table main body 51 and/or the coolant flowing in the coolant path 55. At this time, it is preferable to circulate the coolant in the coolant path 55 such that the plastic substrate S is sufficiently cooled.

When the inside of the processing chamber 2 is set to a depressurized atmosphere, a predetermined inert gas such as nitrogen or a rare gas such as argon, helium or the like is introduced from the gas nozzles 31A and 31B into the processing chamber 2 and the inside of the processing chamber 2 is exhausted by the gas exhaust unit 4. Accordingly, the depressurized atmosphere in the processing chamber 2 is formed. Or, the inside of the processing chamber 2 is set to an atmospheric atmosphere without being exhausted.

In this state, the electromagnetic waves having a predetermined wavelength, which are generated by the electromagnetic wave generation source 81 of the electromagnetic wave supply unit 8, are transmitted to the incident antenna 83 via the waveguide 82 and introduced into the processing chamber 2 while penetrating through the ceiling plate 22.

The electromagnetic waves introduced into the processing chamber 2 are irradiated to the device sheet D, and the coating film C is dried or modified. At this time, the plastic substrate S is hardly heated because the electromagnetic waves are not absorbed thereinto. The coating film C absorbs the energy of the electromagnetic waves. The solvent, the dispersing agent or the like is heated and evaporated mainly by dielectric loss. The film components (metallic nanoparticles, organic semiconductor material, organic dielectric material) are modified by selective heating using the difference in the induction loss, the dielectric loss, and the magnetic loss depending on the types of materials. Therefore, the coating film obtained by irradiating electromagnetic waves has extremely high properties (electrical conductivity, semiconductor properties, dielectric properties) even before the electromagnetic wave irradiation.

After the initial electromagnetic wave annealing is completed in the above manner, the irradiation of the electromagnetic waves is stopped, and the device sheet D is transferred until a next portion to be processed of the device sheet D is mounted on the mounting table 5. Thereafter, the next electromagnetic wave irradiation is performed. In case the annealing is performed under the depressurized atmosphere, the pressure in the processing chamber 2 is returned to an atmospheric pressure and then, the shutters 2A and 2B are opened so that the device sheet D is transferred until the next portion to be processed of the device sheet D is mounted on the mounting table 5. Next, the same process is carried out. These operations are sequentially repeated until the last portion of the device sheet D is subjected to the electromagnetic wave annealing.

Hereinafter, another example of a film forming apparatus using the film forming method of the present embodiment will be described.

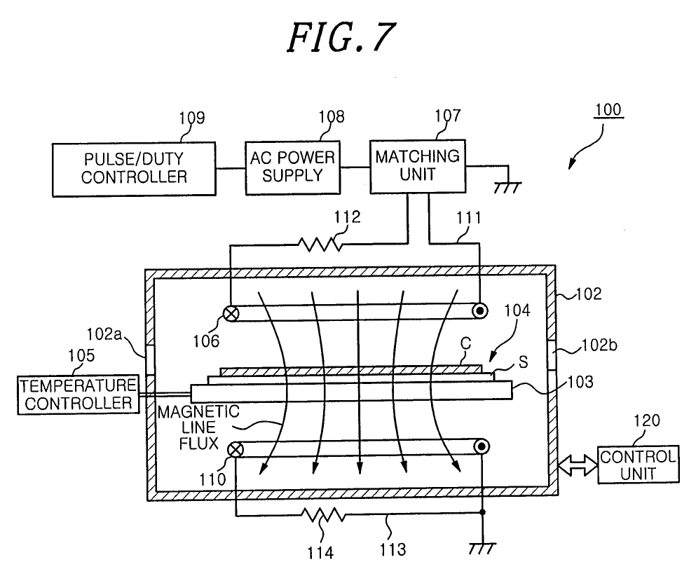

FIG. 7 is a cross sectional view showing another example of a film forming apparatus using the film forming method of the present embodiment.

The film forming apparatus 100 includes a processing chamber 102 made of a material having an electromagnetic wave shield function such as stainless steel (SUS), aluminum or the like. A cooling plate 103 made of undoped silicon, aluminum nitride (AlN), silicon carbide (SiC), alumina (Al₂O₃) or the like is provided in the processing chamber 102, and a device sheet 104 is mounted on the cooling plate 103. The device sheet 104 has a coating film C of a predetermined pattern formed on a plastic substrate S, by coating a coating composition containing film components on the plastic substrate S. In other words, the cooling plate 103 serves as a supporting member of the device sheet 104. The device sheet 104 is loaded through a loading port 102a of the processing chamber 102 and unloaded through an unloading port 102b. The cooling plate 103 is connected to a temperature controller 105 for controlling a temperature of the substrate by controlling, e.g., a temperature of a circulating cooling medium. Further, a resistance heater may be provided in the cooling plate 103 to heat the plastic substrate S to a temperature lower than the heat resistance temperature of the plastic substrate S.

A ring-shaped transmission antenna 106 for transmitting electromagnetic waves is provided at an upper portion in the processing chamber 102 to correspond to the cooling plate 103. An AC current having a frequency of, e.g., about 100 Hz to 50 kHz, is supplied from an AC power supply 108 to the transmission antenna 106 via a matching unit 107. A pulse/duty controller 109 is connected to the AC power supply 108 and controls the AC current output from the AC power supply 108 to have a pulse shape of a predetermined duty ratio. Further, a matching load 112 is connected to a power supply line 111 for supplying power to the transmission antenna 106.

Meanwhile, a ring-shaped reception antenna 110 for receiving electromagnetic waves transmitted from the transmission antenna 106 is disposed below the cooling plate 103 to correspond to the transmission antenna 106. A ground line 113 is connected to the reception antenna 110, and a matching load 114 is connected to the ground line 113.

Therefore, when the AC current is supplied from the AC power source 108 to the transmission antenna 106, a magnetic field penetrating the transmission antenna 106 and the reception antenna 110 is generated, and the electromagnetic waves with the frequency of the AC power source 108 are irradiated to the device sheet 104 by electromagnetic induction.

The film forming apparatus 100 includes a control unit 120. The control unit 120 has a microprocessor (computer) and controls the respective components of the film forming apparatus 100 based on signals from the sensors, for example. The control unit 120 has a storage unit storing process recipes such as control parameters and process sequences of the film forming apparatus 100, an input unit, a display or the like, and controls the film forming apparatus 100 in accordance with a selected process recipe.

Hereinafter, the operation of the film forming apparatus 100 configured as described above will be explained.

First, the device sheet 104 having the coating film C formed by coating a coating composition containing film components on the plastic substrate S such as PET, PEN, PC, PI or the like is loaded through the loading port 102a and mounted on the cooling plate 103. The cooling plate 103 is maintained at a proper temperature ranging from a room temperature to 100° C. by the temperature controller 105.

In this state, an AC current with a frequency of, e.g., about 100 Hz to 50 kHz, is supplied from the AC power supply 108 to the transmission antenna 106 via the matching unit 107. Hence, a magnetic field penetrating the transmission antenna 106 and the reception antenna 110 is generated, and electromagnetic waves with a frequency of the AC power supply 108 are irradiated to the device sheet 104 by electromagnetic induction. At this time, the plastic substrate S may be cooled by controlling the AC current output from the AC power supply 108 to have a pulse shape of a predetermined duty ratio by the pulse/duty controller 109.

By irradiating electromagnetic waves to the device sheet 104 in the processing chamber 102, the energy of the electromagnetic waves is absorbed into the coating film C and the coating film C is dried and/or modified by induction loss or the like. In other words, a solvent, a dispersing agent or the like is heated, evaporated and removed mainly by dielectric loss; and the film components (metallic nanoparticles, organic semiconductor material and organic dielectric material) are modified by selective heating using the difference in the induction loss the dielectric loss and the magnetic loss depending on the types of materials. Specifically, in the case of the coating film using metallic nanoparticles, a conductive film having high electrical conductivity can be formed. In the case of the coating film using an organic semiconductor material, a semiconductor film having excellent semiconductor properties (mobility and ON/OFF ratio) can be formed. In the case of the coating film using an organic dielectric material, a dielectric film having original dielectric characteristics of a dielectric film, e.g., high capacity, a small leakage current, high stability and high reliability which are required for the gate insulating film, can be formed. At this time, the plastic substrate S is hardly heated because electromagnetic waves are not absorbed thereinto. Since the plastic substrate is hardly heated, a film having good properties can be formed by applying a coating printing technique to the plastic substrate.

At this time, the irradiated electromagnetic waves have a frequency suitable for the coating composition. For example, when the coating composition contains Ag nanoparticles, the frequency of about 100 GHz is used. Further, in the case of using CHCl₃ solution of P3HT as a coating composition, in the dielectric dispersion of FIG. 3, electromagnetic waves of a frequency band (e.g., about 1 Hz to 10 kHz) corresponding to the peak of the imaginary part of the complex permittivity, preferably electromagnetic waves with a frequency of about 400 Hz as the peak position or near-peak, are irradiated. In the case of using the liquid PVP as a coating composition, in the dielectric dispersion of FIG. 5, electromagnetic waves of a frequency band (e.g., about 100 Hz to 50 kHz) corresponding to the peak of the imaginary part of the complex permittivity, preferably electromagnetic waves with a frequency of about 2 kHz to 4 kHz as the peak position or near-peak, are irradiated.

Even when a special cooling mechanism is not used for the plastic substrate S, only the coating film C can be selectively heated transiently without heating the plastic substrate S. However, as the irradiation time is increased, the temperature of the plastic substrate S may be increased by heat transfer. Therefore, the plastic substrate S can be cooled by the cooling plate 103, the temperature increase of the plastic substrate S can be more effectively suppressed by cooling the plastic substrate S by the cooling plate 103 or controlling the duty ratio by transmitting the electromagnetic waves in a pulse shape.

If a higher temperature is required for drying and/or modifying the coating film C, the coating film C may be heated to a temperature equal to or less than the heat resistance temperature of the plastic substrate S by providing the resistance heater or the like in the cooling plate 10.

After the desired dielectric film is formed by irradiating electromagnetic waves in the above manner, the device sheet 104 is unloaded through the unloading port 102b.

In the film forming apparatus 100 shown in FIG. 7, the temperature controller 105 is used. However, when the cooling can be sufficiently performed by heat capacity of the cooling plate 103, the temperature controller 105 is not necessarily required. Moreover, although electromagnetic waves can be stably irradiated by using the transmission antenna 106 and the reception antenna 110, the reception antenna 110 is not necessarily required.

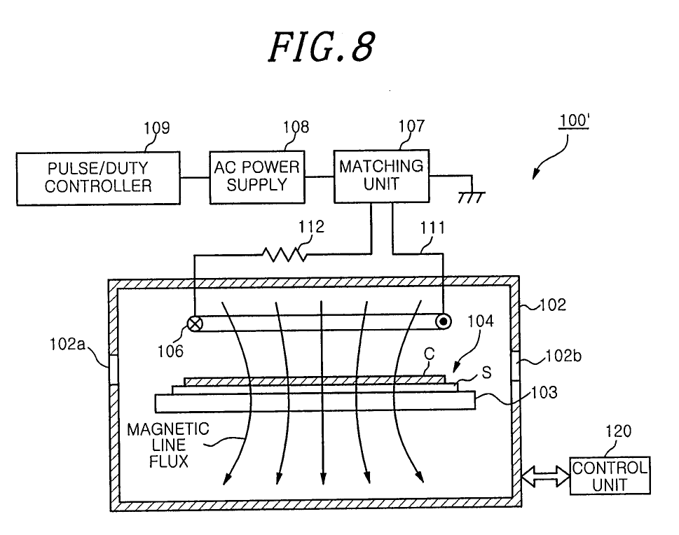

FIG. 8 shows a structure of a film forming apparatus 100′ that includes no temperature controller and no reception antenna. In the device having such structure, a desired film can be formed by drying and/or modifying the coating film C without heating the plastic substrate S by irradiating electromagnetic waves to the device sheet 104 as in the device shown in FIG. 7. The apparatus in which either one of the temperature controller 105 or the reception antenna 110 is omitted from the apparatus shown in FIG. 7 may also be used.

As described above, in accordance with the present embodiment, the coating film, containing film components is formed on the plastic substrate and dried and/or modified by irradiating electromagnetic waves thereto. Therefore, the plastic substrate is hardly heated, and a film having good properties can be formed on the plastic substrate without heating the plastic substrate to a high temperature.

In the present embodiment, a film having good properties can be formed by applying a coating printing technique to the plastic substrates, and such film may be a conductor film, a semiconductor film, and a dielectric film. Therefore, the present embodiment is suitable for the formation of a wiring, a semiconductor film, a gate insulating film or the like in the case of forming a thin film transistor (TFT) on the plastic substrate. Further, it is suitable for the formation of a semiconductor film as a photoelectric conversion device for a solar cell on the plastic substrate.

The present invention can be variously modified without being limited to the above embodiment. For example, in the above embodiment, a film serving as wiring is formed after a coating film pattern (e.g., wiring pattern) is formed by coating a coating composition and electromagnetic waves are irradiated thereto. However, the present invention is not limited thereto, and a wiring pattern may be formed after a coating film is formed by coating a coating composition on the entire surface of a plastic substrate and electromagnetic waves are irradiated thereto. In addition, a wiring pattern may be formed after the electromagnetic waves are irradiated while spraying a mist of coating composition onto the plastic substrate. Therefore, a solvent or a dispersing agent in the mist of coating composition may be removed by electromagnetic waves. The metallic particles are mainly attached to the plastic substrate, so that the aggregation is facilitated by the electromagnetic waves and the electrical conductivity can be further increased.

In the above embodiment, only electromagnetic waves are irradiated to the coating film formed by coating a coating composition. However, the electromagnetic waves may be irradiated after the coating film is processed by the gas plasma such as Ar gas, O₂ gas, H₂ gas or the like. In other words, first, the solvent or the dispersing agent in the coating composition is removed by the gas plasma and then, the electromagnetic waves are irradiated to modify (aggregate) the film components such as metallic nanoparticles or the like. Accordingly, the modification of the film components (aggregation of metallic nanoparticles) is facilitated, and the electrical conductivity can be further increased.

The film forming apparatus of the above embodiment is only an example. The film forming apparatus is not limited thereto as long as a desired film can be formed by drying and/or modifying a coating film formed on a plastic substrate by irradiating electromagnetic waves thereto while suppressing temperature increase of the plastic substrate.

What is claimed is:

1. A film forming method, comprising:
coating, on a plastic substrate, a coating composition containing film components to form a coating film; and
irradiating the coating film with electromagnetic waves to dry and/or modify the coating film, and form a film.

2. The film forming method of claim 1, wherein the coating composition contains metallic nanoparticles, and the coating film is formed as a wiring material formed of the metallic nanoparticles by irradiating the coating film with the electromagnetic waves.

3. The film forming method of claim 2, wherein the coating film is formed as a wiring pattern before annealing is performed by irradiating the electromagnetic waves, and the electromagnetic waves are irradiated to at least the wiring pattern.

4. The film forming method of claim 2, wherein the coating film is coated on an entire surface of the plastic substrate, and a wiring pattern is formed after the electromagnetic waves are irradiated to the coating film coated on the entire surface.

5. The film forming method of claim 2, wherein the coating film is processed by a gas plasma before annealing is performed by irradiating the electromagnetic waves.

6. The film forming method of claim 2, wherein the electromagnetic waves are irradiated while spraying the coating composition onto the plastic substrate and then, a wiring pattern is formed on the coating film formed on the plastic substrate.

7. The film forming method of claim 1, wherein the coating composition contains an organic semiconductor material.

8. The film forming method of claim 7, wherein a frequency of the electromagnetic waves is set to a frequency at which absorption of the electromagnetic waves into the plastic substrate is low and absorption of the electromagnetic waves into the coating composition containing the organic semiconductor material is high.

9. The film forming method of claim 8, wherein the frequency of the electromagnetic waves is an absorption peak value of dielectric dispersion properties of the coating composition or a value near the peak value.

10. The film forming method of claim 7, wherein the coating composition is a solution in which poly-3-hexylthiophene (P3HT), as an organic semiconductor material is dissolved in chloroform (CHCl₃).

11. The film forming method of claim 7, wherein the electromagnetic waves have a frequency of about 1 Hz to 10 kHz.

12. The film forming method of claim 1, wherein the coating composition contains an organic dielectric material.

13. The film forming method of claim 12, wherein the frequency of the electromagnetic waves is set to a frequency at which absorption of the electromagnetic waves into the plastic substrate is low and absorption of the electromagnetic waves into the coating composition containing the organic dielectric material is high.

14. The film forming method of claim 13, wherein the frequency of the electromagnetic waves is an absorption peak value of dielectric dispersion properties of the coating composition or a value near the peak value.

15. The film forming method of claim 12, wherein the coating composition is liquid polyvinyl phenol as an organic dielectric material.

16. The film forming method of claim 12, wherein the electromagnetic waves have a frequency of about 100 Hz to 50 kHz.

17. The film forming method of claim 1, wherein the electromagnetic waves are irradiated while cooling the plastic substrate.

18. The film forming method of claim 1, wherein the electromagnetic waves are irradiated in a pulsed manner.

19. The film forming method of claim 1, wherein the electromagnetic waves are irradiated while heating the substrate to a temperature equal to or lower than a heat resistance temperature of the plastic substrate.
